(19) United States
(12) Patent Application Publication
(10) Pub. No.: US 2019/0222352 A1
(43) Pub. Date: Jul. 18, 2019

(54) OPTICAL RECEIVER AND ERROR CORRECTION METHOD OF THE OPTICAL RECEIVER

(71) Applicant: ELECTRONICS AND TELECOMMUNICATIONS RESEARCH INSTITUTE, Daejeon (KR)

(72) Inventors: Sang Rok MOON, Daejeon (KR); Hun Sik KANG, Daejeon (KR)

(73) Assignee: ELECTRONICS AND TELECOMMUNICATIONS RESEARCH INSTIT UTE, Daejeon (KR)

(21) Appl. No.: 16/112,628

(22) Filed: Aug. 24, 2018

(30) Foreign Application Priority Data
Jan. 16, 2018 (KR) 10-2018-0005721
May 11, 2018 (KR) 10-2018-0054442

(51) Int. Cl. H04L 1/00; H04B 10/67; H04B 10/50; H03M 13/39; G06N 99/00

(52) U.S. Cl. CPC H04L 1/0047; H04B 10/67; G06N 99/005; H04L 1/0076; H03M 13/3927; H04B 10/50

(57) ABSTRACT

Disclosed is an optical receiver and an error correction method performed by the optical receiver, receiving, using a receiving antenna or a photodetector, a training signal in which an error occurs due to noise and distortion while being output from an optical transmitter and transmitted through a communication channel and identifying a hyperplane for classifying a probability that the received training signal is a training signal corresponding to a training signal output from the optical signal using a support vector machine (SVM) and learning a parameter of the identified hyperplane such that a classification error probability is minimized when the probability is extracted using the identified hyperplane, wherein the parameter of the identified hyperplane is used to correct an error occurring while a transmission signal output from the optical signal is received using the receiving antenna or the photodetector.

### CROSS-REFERENCE TO RELATED APPLICATION(S)

This application claims the priority benefit of Korean Patent Application No. 10-2018-0005721 filed on Jan. 16, 2018 and Korean Patent Application No. 10-2018-0054442 filed on May 11, 2018, in the Korean Intellectual Property Office, the disclosures of which are incorporated herein by reference for all purposes.

### BACKGROUND

### 1. Field

One or more example embodiments relate to an optical receiver and an error correction method of the optical receiver and, more particularly, to a method and apparatus for performing a forward error correction (FEC) using a support vector machine (SVM) of machine learning schemes.

### 2. Description of Related Art

When a signal is transmitted through a communication channel, an error may occur in the signal due to noise and distortion exist in the channel. In this instance, a forward error correction (FEC) technique may be used as a technique for detecting or correcting the error. The FEC technique may transmit a signal including an additional overhead and use information generated from the transmitted overhead to correct an error occurring in the signal. As a result, although a transmission rate of a data signal transmitted through the communication channel is slightly reduced, an error rate may also be reduced.

A soft input may be used to improve a performance of the FEC technique. A hard input may receive a preset value, for example, 0 or 1 as an input. In contrast, the soft input may receive a probability that a signal transmitted through a communication channel is 0 and 1. For example, a signal having a nonreturn-to-zero (NRZ) format, which is represented by 0 and 1, may pass a transmission channel and be input to a low density parity check (LDPC), one of FEC techniques using the soft input. The LDPC may correct an error occurring in a received signal using a log likelihood ratio (LLR) generated by applying a log value to a ratio between a probability of an input signal being 1 and a probability of an input signal being 0.

To calculate the LLR, a noise distribution of the received signal may need to be known. In general, a Gaussian distribution may be assumed as the noise distribution. However, when the noise distribution is not the Gaussian distribution or a channel distortion is incompletely compensated, the performance of the error correction may be degraded. Such degradation may be generally applied to the FEC using the soft input in addition to the LDPC. To solve this, an algorithm or an apparatus for obtaining the noise distribution may be required. In some cases, it is difficult to obtain an actual noise distribution.

### SUMMARY

An aspect provides an optical receiver and an error correction method of the optical receiver. Specifically, a method and apparatus for performing a forward error correction (FEC) using a support vector machine (SVM) of machine learning schemes is provided.

According to an aspect, there is provided an error correction method performed by an optical receiver, the method including receiving, using a receiving antenna or a photodetector, a training signal in which an error occurs due to noise and distortion while being output from an optical transmitter and transmitted through a communication channel and identifying a hyperplane for classifying a probability that the received training signal is a training signal corresponding to a training signal output from the optical signal using an SVM and learning a parameter of the identified hyperplane such that a classification error probability is minimized when the probability that the received training signal is the training signal corresponding to the training signal output from the optical transmitter is extracted using the identified hyperplane, wherein the parameter of the identified hyperplane is used to correct an error occurring while a transmission signal output from the optical signal is received using the receiving antenna or the photodetector.

The training signal may be a signal agreed upon between the optical transmitter and the optical receiver.

The training signal output from the optical transmitter may have a value of 0 or 1, and the identifying may include updating the parameter of the hyperplane by determining a probability that the training signal output from the optical transmitter and received using the receiving antenna or the photodetector has the value of 0 or 1 using the identified hyperplane.

The identifying may include generating a probability table showing a probability that the received training signal is classified as the training signal corresponding to the training signal output from the optical transmitter based on a probability that the received training signal has a value of 0 or 1.

According to another aspect, there is also provided an optical receiver including a receiving antenna or a photodetector configured to receive a training signal in which an error occurs due to noise and distortion while being output from an optical transmitter and transmitted through a communication channel and a processor configured to identify a hyperplane for classifying a probability that the received training signal is a training signal corresponding to a training signal output from the optical signal using an SVM and learn a parameter of the identified hyperplane such that a classification error probability is minimized when the probability that the received training signal is the training signal corresponding to the training signal output from the optical transmitter is extracted using the identified hyperplane, wherein the parameter of the identified hyperplane is used to correct an error occurring while a transmission signal output from the optical signal is received using the receiving antenna or the photodetector.

The training signal may be a signal agreed upon between the optical transmitter and the optical receiver.

The training signal output from the optical transmitter may have a value of 0 or 1, and the processor may be configured to update the parameter of the hyperplane by determining a probability that the training signal output from the optical transmitter and received using the receiving antenna or the photodetector has the value of 0 or 1 using the identified hyperplane.

The processor may be configured to generate a probability table showing a probability that the received training signal is classified as the training signal corresponding to the training signal output from the optical transmitter based on a probability that the received training signal has a value of 0 or 1.

The optical receiver may further include a memory configured to store an output value of the processor and the memory may store the learned parameter of the hyperplane or the generated probability table.

According to still another aspect, there is also provided an error correction method performed by an optical receiver, the method including receiving, using a receiving antenna or a photodetector, a transmission signal in which an error occurs due to noise and distortion while being output from an optical transmitter and transmitted through a communication channel, extracting, using an SVM, a probability that the transmission signal received using the receiving antenna or the photodetector is a transmission signal corresponding to a transmission signal output from the optical transmitter, determining a log likelihood ratio (LLR) with respect to the extracted probability, and correcting the error occurring in the transmission signal received using the receiving antenna or the photodetector based on the determined LLR, wherein the SVM is configured to identify a hyperplane for classifying a probability that a training signal received using the receiving antenna or the photodetector is a training signal corresponding to a training signal output from the optical transmitter, and learn, using the identified hyperplane, a parameter of the identified hyperplane such that a classification error probability is minimized when the probability that the received training signal is the training signal corresponding to the training signal output from the optical transmitter is extracted.

The error correction method may further include performing a hard decision on the extracted probability using a slicer and updating the parameter of the hyperplane by training the SVM using a result value of the hard decision, wherein the extracting may include extracting a probability that the transmission signal received using the receiving antenna or the photodetector is the transmission signal corresponding to the transmission signal output from the optical transmitter, using an SVM having the updated parameter of the hyperplane.

The extracting may include extracting, using a probability table, the probability that the transmission signal received using the receiving antenna or the photodetector is the transmission signal corresponding to the transmission signal output from the optical transmitter, and the probability table may be generated using a probability that the received training signal is classified as the training signal corresponding to the training signal output from the optical transmitter.

The training signal may be a signal agreed upon between the optical transmitter and the optical receiver.

According to yet another aspect, there is also provided an optical receiver including a receiving antenna or a photodetector configured to receive a transmission signal in which an error occurs due to noise and distortion while being output from an optical transmitter and transmitted through a communication channel and a processor configured to extract, using an SVM, a probability that the transmission signal received using the receiving antenna or the photodetector is a transmission signal corresponding to a transmission signal output from the optical transmitter, determine an LLR with respect to the extracted probability, and correct the error occurring in the transmission signal received using the receiving antenna or the photodetector based on the determined LLR, wherein the SVM is configured to identify a hyperplane for classifying a probability that a training signal received using the receiving antenna or the photodetector is a training signal corresponding to a training signal output from the optical transmitter, and learn, using the identified hyperplane, a parameter of the identified hyperplane such that a classification error probability is minimized when the probability that the received training signal is the training signal corresponding to the training signal output from the optical transmitter is extracted.

The processor may be configured to perform a hard decision on the extracted probability using a slicer, update the parameter of the hyperplane by training the SVM using a result value of the hard decision, and extract a probability that the transmission signal received using the receiving antenna or the photodetector is the transmission signal corresponding to the transmission signal output from the optical transmitter, using an SVM having the updated parameter of the hyperplane.

The processor may be configured to extract, using a probability table, the probability that the transmission signal received using the receiving antenna or the photodetector is the transmission signal corresponding to the transmission signal output from the optical transmitter, and the probability table may be generated using a probability that the received training signal is classified as the training signal corresponding to the training signal output from the optical transmitter.

The training signal may be a signal agreed upon between the optical transmitter and the optical receiver.

Additional aspects of example embodiments will be set forth in part in the description which follows and, in part, will be apparent from the description, or may be learned by practice of the disclosure.

### BRIEF DESCRIPTION OF THE DRAWINGS

These and/or other aspects, features, and advantages of the invention will become apparent and more readily appreciated from the following description of example embodiments, taken in conjunction with the accompanying drawings of which:

FIG. 1 is a diagram illustrating an optical receiver performing an error correction method using a support vector machine (SVM) according to an example embodiment;

FIG. 2 is a diagram illustrating an example of an error correction method performed by an optical receiver according to an example embodiment;

FIG. 3 is a diagram illustrating another example of an error correction method performed by an optical receiver according to an example embodiment; and

FIGS. 4A through 4D are diagrams illustrating results obtained by configuring a probability table using a 4-quadrature amplitude modulation (QAM) training signal and an SVM according to an example embodiment.

### DETAILED DESCRIPTION

Hereinafter, example embodiments will be described in detail with reference to the accompanying drawings. It should be understood, however, that there is no intent to limit this disclosure to the particular example embodiments disclosed. On the contrary, example embodiments are to cover all modifications, equivalents, and alternatives falling within the scope of the example embodiments.

The terminology used herein is for the purpose of describing particular embodiments only and is not intended to be limiting. As used herein, the singular forms “a,” “an,” and “the,” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

Unless otherwise defined, all terms, including technical and scientific terms, used herein have the same meaning as commonly understood by one of ordinary skill in the art to which this disclosure pertains. Terms, such as those defined in commonly used dictionaries, are to be interpreted as having a meaning that is consistent with their meaning in the context of the relevant art, and are not to be interpreted in an idealized or overly formal sense unless expressly so defined herein.

Regarding the reference numerals assigned to the elements in the drawings, it should be noted that the same elements will be designated by the same reference numerals, wherever possible, even though they are shown in different drawings. Also, in the description of embodiments, detailed description of well-known related structures or functions will be omitted when it is deemed that such description will cause ambiguous interpretation of the present disclosure.

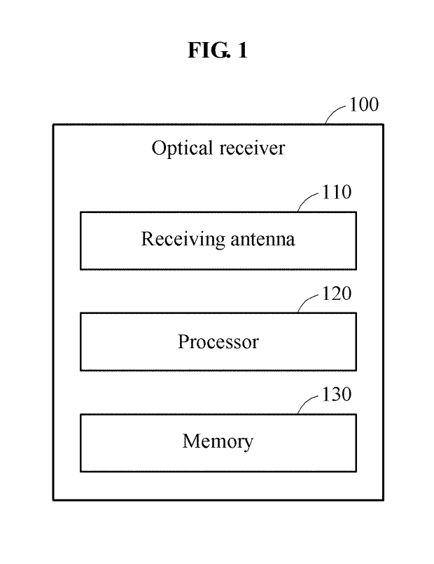

FIG. 1 is a diagram illustrating an optical receiver performing an error correction method using a support vector machine (SVM) according to an example embodiment.

Referring to FIG. 1, an optical receiver 100 may include a receiving antenna 110 or a photodetector, a processor 120, and a memory 130. The receiving antenna 110 or the photodetector may receive a transmission signal or a training signal output from a transmitting antenna of an optical transmitter and transmitted through a communication channel. In the training signal or the transmission signal received by the receiving antenna 110 or the photodetector, an error may occur due to noise and distortion while the training signal or the transmission signal is transmitted through the communication signal. In this example, the training signal may be a signal agreed upon between the optical transmitter and the optical receiver 100.

The processor 120 may identify a hyperplane for classifying a probability that the received training signal is a training signal corresponding to a training signal output from the optical transmitter using an SVM. Also, the processor 120 may learn a parameter of the identified hyperplane such that a classification error probability is minimized when the probability that the received training signal is the training signal corresponding to the training signal output from the optical transmitter is extracted using the identified hyperplane. The learned parameter may be stored in the memory 130.

Likewise, the processor 120 may extract a probability that the transmission signal received by the receiving antenna 110 or the photodetector is a transmission signal corresponding to a transmission signal output from the optical transmitter based on the parameter of the hyperplane learned using the SVM.

The processor 120 may correct the error occurring in the received transmission signal by applying a soft input FEC using the extracted probability. Specifically, the processor 120 may determine a log likelihood ratio (LLR) with respect to the extracted probability and correct the error occurring in the received transmission signal based on the determined LLR. As such, the processor 120 may calculate the LLR to which an actual noise distribution affecting the received transmission signal is applied using the soft input FEC, thereby improving the performance of the error correction.

The SVM may be a machine learning scheme that allows a machine to autonomously learn and set a model and/or an algorithm for deriving a result from data. The SVM may be one of representative machine learning schemes associated with supervised learning that is used for pattern classification. The SVM may identify a hyperplane, for example, a hyper-space for optimally classifying a given pattern using the training signal and classify the training signal using the identified hyperplane. In this example, the hyperplane may indicate a plane having a dimension lower than that of the data by one dimension.

The training signal transmitted through the communication channel may be, for example, a quadrature amplitude modulation (QAM) signal. The QAM signal may be expressed by an in-phase signal and a quadrature signal and thus, may be indicated on a two-dimensional (2D) plane. The SVM may temporarily convert data to have a high dimension using a suitable type of kernel function, for example, a Gaussian radial basis kernel function and classify a signal by detecting a hyperplane for optimally classifying the data, for example, minimizing a cost function defined by the SVM. The SVM trained using the training signal may classify a transmission signal using the hyperplane in response to the transmission signal being received, calculate a probability that the transmission signal received by the receiving antenna 110 or the photodetector is classified as a transmission signal corresponding to a transmission signal output from the optical transmitter, and output the calculated probability.

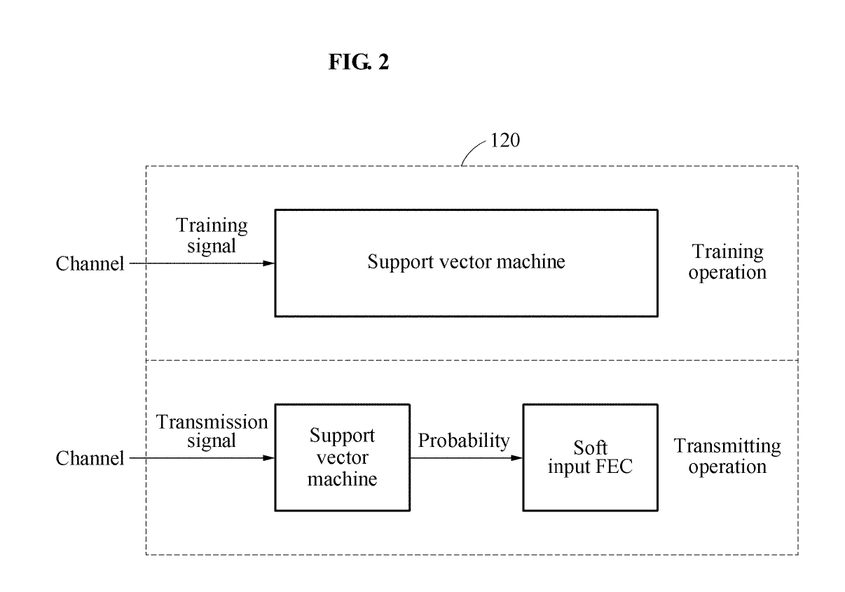

FIG. 2 is a diagram illustrating an example of an error correction method performed by an optical receiver according to an example embodiment.

In a training operation, the processor 120 may receive a training signal in which an error occurs due to noise and distortion while being output from an optical transmitter and transmitted through a communication channel. In this example, the received training signal may be a signal agreed upon between the optical transmitter and an optical receiver.

The processor 120 may identify a hyperplane for classifying a probability that the received training signal is a training signal corresponding to a training signal output from the optical transmitter using an SVM. Specifically, the training signal output from the optical transmitter may have a value of 0 or 1. For example, the training signal output from the optical transmitter may have a value of 0. In the training signal having the value of 0, an error may occur due to the noise and the distortion while being transmitted through the communication channel. In this example, the training signal may have a value other than the value of 0 in the optical receiver. The optical receiver may be aware of information on the training signal and thus, determine a parameter of the hyperplane such that the training signal in which the error occurs is classified as the value of 0.

As such, the processor 120 may train the SVM using the agreed training signal to minimize a classification error probability when extracting the probability that the received training signal is the training signal corresponding to the training signal output from the optical transmitter.

In a transmitting operation, the processor 120 may receive a transmission signal in which an error occurs due to noise and distortion while being output from the optical transmitter and transmitted through the communication channel. Thereafter, the processor 120 may extract a probability that the received transmission signal is a transmission signal corresponding to a transmission signal output from the optical transmitter using a hyperplane determined by training the SVM in the training operation.

The processor 120 may correct the error occurring in the received transmission signal by applying a soft input FEC using the extracted probability. Specifically, the processor 120 may determine an LLR with respect to the extracted probability and correct the error occurring in the received transmission signal based on the determined LLR. As such, the processor 120 may calculate the LLR to which an actual noise distribution affecting the received transmission signal is applied using the soft input FEC, thereby improving the performance of the error correction.

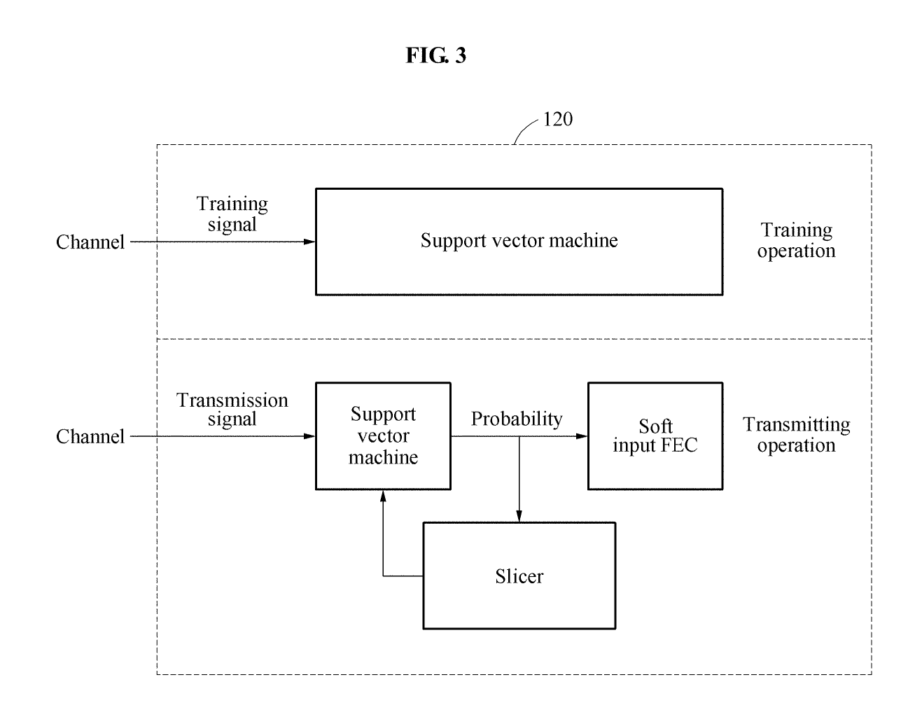

FIG. 3 is a diagram illustrating another example of an error correction method performed by an optical receiver according to an example embodiment.

Referring to FIG. 3, an additional scheme may be provided to prevent a degradation occurring in an SVM in response to a channel characteristic changing while a transmission signal is transmitted to an optical receiver through an optical transmitter. Since the description of FIG. 2 is also applicable here, repeated description about a training operation will be omitted.

In a transmitting operation, the processor 120 may receive a transmission signal in which an error occurs due to noise and distortion while being output from the optical transmitter and transmitted through a communication channel. Thereafter, the processor 120 may extract a probability that the received transmission signal is a transmission signal corresponding to a transmission signal output from the optical transmitter using a hyperplane determined by training the SVM in the training operation.

The processor 120 may correct the error occurring in the received transmission signal by applying a soft input FEC using the extracted probability. Specifically, the processor 120 may determine an LLR with respect to the extracted probability and correct the error occurring in the received transmission signal based on the determined LLR. As such, the processor 120 may calculate the LLR to which an actual noise distribution affecting the received transmission signal is applied using the soft input FEC, thereby improving the performance of the error correction.

The processor 120 may perform a hard decision on the extracted probability using a slicer and update a parameter of the hyperplane by training the SVM using a result value of the hard decision. As such, the processor 120 may improve the performance of the error correction by extracting the probability that the received transmission signal is the transmission signal corresponding to the transmission signal output from the optical transmitter using the SVM having the updated parameter of the hyperplane. Also, by using the SVM having the updated parameter of the hyperplane, the processor 120 may prevent the degradation occurring in the SVM in response to the channel characteristic changing while the transmission signal is transmitted to the optical receiver.

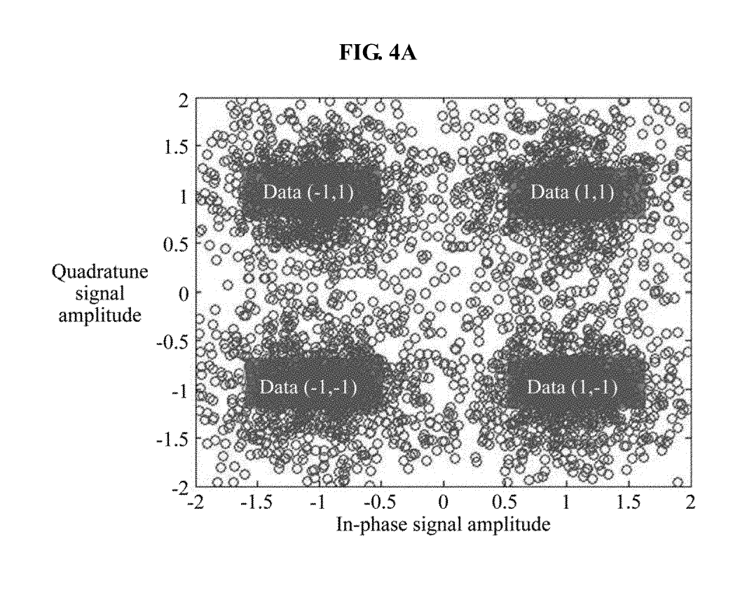

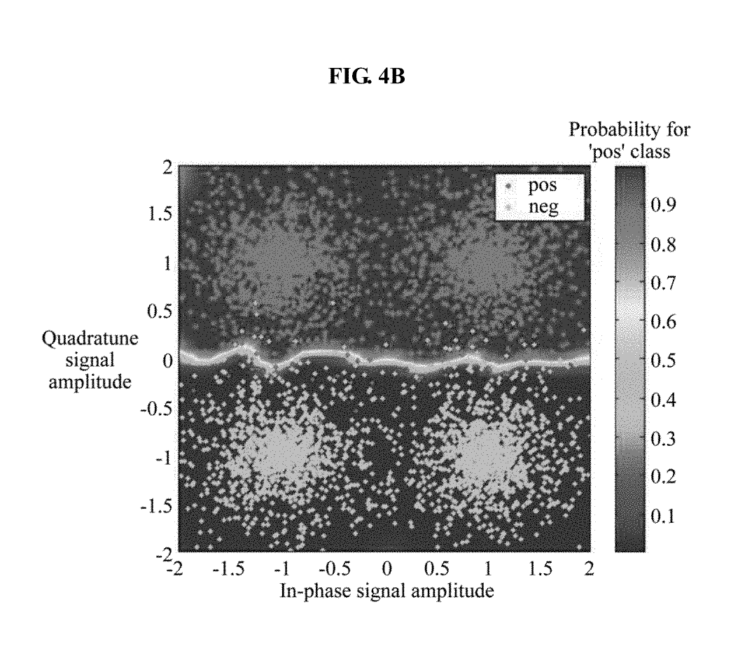

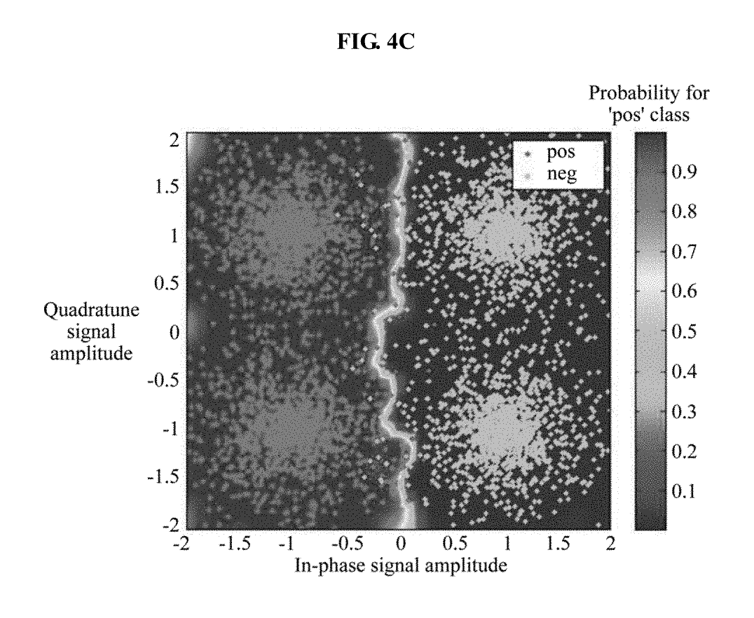

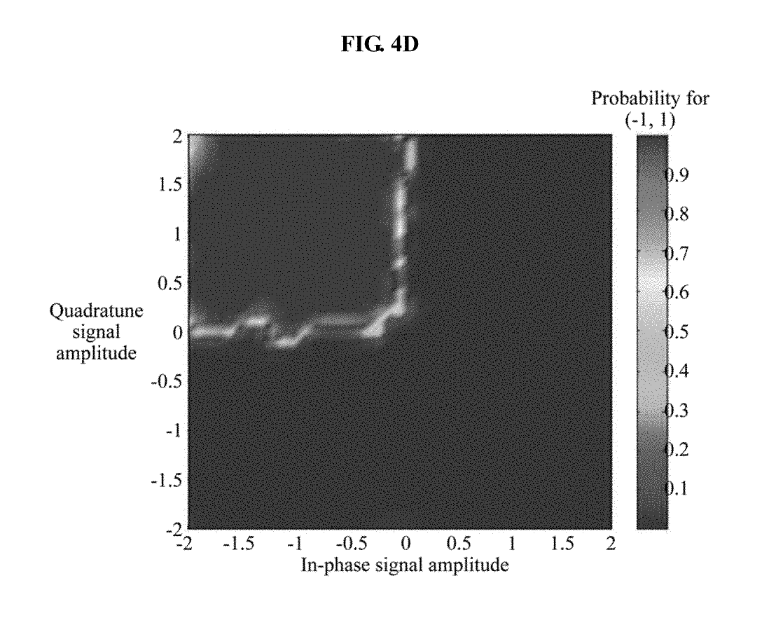

FIGS. 4A through 4D are diagrams illustrating results obtained by configuring a probability table using a 4-QAM training signal and an SVM according to an example embodiment.

The processor 120 may additionally generate a probability table showing a probability that a received training signal is classified as a training signal corresponding to a training signal output from an optical transmitter based on a probability extracted using a parameter of a hyperplane learned using an SVM. In this example, by using the probability table, the processor 120 may extract a probability that a transmission signal received using a receiving antenna or a photodetector is a transmission signal corresponding to a transmission signal output from the optical transmitter. The generated probability table may be stored in the memory 130. As such, by using the generated probability table, the processor 120 may increase a speed of the error correction.

FIG. 4A illustrates a 4-QAM training signal to which noise and distortion is added while being output from the optical transmitter and transmitted through a communication channel. Because the SVM basically divides data into two portions, to generate a probability table using the 4-QAM training signal, two classifying operations may be performed in an in-phase signal direction and a quadrature signal direction. The processor 120 may acquire results of FIGS. 4B and 4C by training an SVM that classifies the received 4-QAM training signal in the in-phase signal direction and an SVM that classifies the received 4-QAM training signal in the quadrature signal direction. FIG. 4D illustrates a probability table generated for a probability that a received training signal is classified as a training signal (−1, 1) output from the optical transmitter by combining probabilities output as a result of training two SVMs. For example, when a training signal is the 4-QAM signal, the processor 120 may generate four probability tables for a probability that a received training signal is classified as a training signal (−1, 1) output from the optical transmitter, a probability that a received training signal is classified as a training signal (1, 1), a probability that a received training signal is classified as a training signal (1, −1), and a probability that a received training signal is classified as a training signal (−1, −1).

Likewise, the processor 120 may generate the probability table using the SVM and calculate a probability that a received transmission signal is classified as a transmission signal corresponding to a transmission signal output from the optical transmitter using the probability table. The processor 120 may correct an error occurring in the received transmission signal by applying a soft input FEC using the calculated probability. Specifically, the processor 120 may determine an LLR with respect to the calculated probability and correct the error occurring in the received transmission signal based on the determined LLR. As such, the processor 120 may calculate the LLR to which an actual noise distribution affecting the received transmission signal is applied using the soft input FEC, thereby improving the performance of the error correction.

According to example embodiments, it is possible to improve a performance of a forward error correction (FEC) using an SVM of machine learning schemes.

The components described in the exemplary embodiments of the present invention may be achieved by hardware components including at least one DSP (Digital Signal Processor), a processor, a controller, an ASIC (Application Specific Integrated Circuit), a programmable logic element such as an FPGA (Field Programmable Gate Array), other electronic devices, and combinations thereof. At least some of the functions or the processes described in the exemplary embodiments of the present invention may be achieved by software, and the software may be recorded on a recording medium. The components, the functions, and the processes described in the exemplary embodiments of the present invention may be achieved by a combination of hardware and software.

The processing device described herein may be implemented using hardware components, software components, and/or a combination thereof. For example, the processing device and the component described herein may be implemented using one or more general-purpose or special purpose computers, such as, for example, a processor, a controller and an arithmetic logic unit (ALU), a digital signal processor, a microcomputer, a field programmable gate array (FPGA), a programmable logic unit (PLU), a microprocessor, or any other device capable of responding to and executing instructions in a defined manner. The processing device may run an operating system (OS) and one or more software applications that run on the OS. The processing device also may access, store, manipulate, process, and create data in response to execution of the software. For purpose of simplicity, the description of a processing device is used as singular; however, one skilled in the art will be appreciated that a processing device may include multiple processing elements and/or multiple types of processing elements. For example, a processing device may include multiple processors or a processor and a controller. In addition, different processing configurations are possible, such as parallel processors.

The methods according to the above-described example embodiments may be recorded in non-transitory computer-readable media including program instructions to implement various operations of the above-described example embodiments. The media may also include, alone or in combination with the program instructions, data files, data structures, and the like. The program instructions recorded on the media may be those specially designed and constructed for the purposes of example embodiments, or they may be of the kind well-known and available to those having skill in the computer software arts. Examples of non-transitory computer-readable media include magnetic media such as hard disks, floppy disks, and magnetic tape; optical media such as CD-ROM discs, DVDs, and/or Blue-ray discs; magneto-optical media such as optical discs; and hardware devices that are specially configured to store and perform program instructions, such as read-only memory (ROM), random access memory (RAM), flash memory (e.g., USB flash drives, memory cards, memory sticks, etc.), and the like. Examples of program instructions include both machine code, such as produced by a compiler, and files containing higher level code that may be executed by the computer using an interpreter. The above-described devices may be configured to act as one or more software modules in order to perform the operations of the above-described example embodiments, or vice versa.

A number of example embodiments have been described above. Nevertheless, it should be understood that various modifications may be made to these example embodiments. For example, suitable results may be achieved if the described techniques are performed in a different order and/or if components in a described system, architecture, device, or circuit are combined in a different manner and/or replaced or supplemented by other components or their equivalents. Accordingly, other implementations are within the scope of the following claims.

What is claimed is:

1. An error correction method performed by an optical receiver, the method comprising:
receiving, using a receiving antenna or a photodetector, a training signal in which an error occurs due to noise and distortion while being output from an optical transmitter and transmitted through a communication channel; and
identifying a hyperplane for classifying a probability that the received training signal is a training signal corresponding to a training signal output from the optical signal using a support vector machine (SVM) and learning a parameter of the identified hyperplane such that a classification error probability is minimized when the probability that the received training signal is the training signal corresponding to the training signal output from the optical transmitter is extracted using the identified hyperplane,
wherein the parameter of the identified hyperplane is used to correct an error occurring while a transmission signal output from the optical signal is received using the receiving antenna or the photodetector.

2. The error correction method of claim 1, wherein the training signal is a signal agreed upon between the optical transmitter and the optical receiver.

3. The error correction method of claim 1, wherein the training signal output from the optical transmitter has a value of 0 or 1, and
the identifying comprises:
updating the parameter of the hyperplane by determining a probability that the training signal output from the optical transmitter and received using the receiving antenna or the photodetector has the value of 0 or 1 using the identified hyperplane.

4. The error correction method of claim 3, wherein the identifying comprises:
generating a probability table showing a probability that the received training signal is classified as the training signal corresponding to the training signal output from the optical transmitter based on a probability that the received training signal has a value of 0 or 1.

5. An error correction method performed by an optical receiver, the method comprising:
receiving, using a receiving antenna or a photodetector, a transmission signal in which an error occurs due to noise and distortion while being output from an optical transmitter and transmitted through a communication channel;
extracting, using a support vector machine (SVM), a probability that the transmission signal received using the receiving antenna or the photodetector is a transmission signal corresponding to a transmission signal output from the optical transmitter;
determining a log likelihood ratio (LLR) with respect to the extracted probability; and
correcting the error occurring in the transmission signal received using the receiving antenna or the photodetector based on the determined LLR,
wherein the SVM is configured to identify a hyperplane for classifying a probability that a training signal received using the receiving antenna or the photodetector is a training signal corresponding to a training signal output from the optical transmitter, and learn, using the identified hyperplane, a parameter of the identified hyperplane such that a classification error probability is minimized when the probability that the received training signal is the training signal corresponding to the training signal output from the optical transmitter is extracted.

6. The error correction method of claim 5, further comprising:
performing a hard decision on the extracted probability using a slicer; and
updating the parameter of the hyperplane by training the SVM using a result value of the hard decision,
wherein the extracting comprises:
extracting a probability that the transmission signal received using the receiving antenna or the photodetector is the transmission signal corresponding to the transmission signal output from the optical transmitter, using an SVM having the updated parameter of the hyperplane.

7. The error correction method of claim 5, wherein the extracting comprises:
extracting, using a probability table, the probability that the transmission signal received using the receiving antenna or the photodetector is the transmission signal corresponding to the transmission signal output from the optical transmitter, and
the probability table is generated using a probability that the received training signal is classified as the training signal corresponding to the training signal output from the optical transmitter.

8. The error correction method of claim 5, wherein the training signal is a signal agreed upon between the optical transmitter and the optical receiver.

9. An optical receiver comprising:
a receiving antenna or a photodetector configured to receive a transmission signal in which an error occurs due to noise and distortion while being output from an optical transmitter and transmitted through a communication channel; and
a processor configured to extract, using a support vector machine (SVM), a probability that the transmission signal received using the receiving antenna or the photodetector is a transmission signal corresponding to a transmission signal output from the optical transmitter, determine a log likelihood ratio (LLR) with respect to the extracted probability, and correct the error occurring in the transmission signal received using the receiving antenna or the photodetector based on the determined LLR,
wherein the SVM is configured to identify a hyperplane for classifying a probability that a training signal received using the receiving antenna or the photodetector is a training signal corresponding to a training signal output from the optical transmitter, and learn, using the identified hyperplane, a parameter of the identified hyperplane such that a classification error probability is minimized when the probability that the received training signal is the training signal corresponding to the training signal output from the optical transmitter is extracted.

10. The optical receiver of claim 9, wherein the processor is configured to perform a hard decision on the extracted probability using a slicer, update the parameter of the hyperplane by training the SVM using a result value of the hard decision, and extract a probability that the transmission signal received using the receiving antenna or the photodetector is the transmission signal corresponding to the transmission signal output from the optical transmitter, using an SVM having the updated parameter of the hyperplane.

11. The optical receiver of claim 9, wherein the processor is configured to extract, using a probability table, the probability that the transmission signal received using the receiving antenna or the photodetector is the transmission signal corresponding to the transmission signal output from the optical transmitter, and
the probability table is generated using a probability that the received training signal is classified as the training signal corresponding to the training signal output from the optical transmitter.

12. The optical receiver of claim 9, wherein the training signal is a signal agreed upon between the optical transmitter and the optical receiver.
